(19) United States
(12) Patent Application Publication
(10) Pub. No.: US 2013/0044063 A1
(43) Pub. Date: Feb. 21, 2013

(54) TOUCH CORRECTING KEYPAD

(71) Applicant: Taesung Kim, Los Altos, CA (US)

(72) Inventor: Taesung Kim, Los Altos, CA (US)

(73) Assignee: APPLE INC., Cupertino, CA (US)

(21) Appl. No.: 13/213,173

(22) Filed: Aug. 19, 2011

(51) Int. Cl. G06F 3/041; H03M 11/00

(52) U.S. Cl. 345/173; 341/22

(57) ABSTRACT

Disclosed embodiments relate to an adaptable touch keypad that adapts a key layout based at least in part upon detected typographical usage patterns of a user. The key layout may include an input region and graphical representation region for each key of the adaptable touch keypad. A processor of an electronic device may monitor for usage patterns of the adaptable touch keypad over time. The processor may modify the key layout (e.g., the input regions and/or the graphical representation regions) based upon the usage patterns.

### BACKGROUND

The present disclosure relates generally to touch screen keypads, and, more particularly, to touch screen keypads that adapt to typographical usage.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

Many electronic devices include touch screen displays that enable a user to interact with a touch keypad provided on the touch screen display during operation of the electronic device. The touch keypads are limited by the size and shape of the touch screen display. Thus, the keys on these touch keypads are often smaller than may be desired, and in some instances may lead to numerous typographical errors.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

Embodiments of the present disclosure relate to devices and methods for reducing typographical errors on touch screen keypads. In some embodiments, a dynamically adaptable keypad may be provided by the electronic device to attempt to reduce the number of typographical errors produced by the user of the keypad. For example, an electronic device may provide a touch screen keypad and may monitor the typographical usage of a user. The electronic device may modify the keypad layout (e.g., the size, shape, and/or placement of the graphical representation and/or input regions keys of the keypad).

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings in which:

FIG. 1 is a schematic block diagram of an electronic device with a touch screen display that provides a dynamically adaptable touch keypad, in accordance with an embodiment;

FIG. 2 is a perspective view of a handheld electronic device with an adaptable touch keypad, in accordance with an embodiment;

FIG. 3. is a perspective view of the handheld electronic device of FIG. 2, rotated 90 degrees, in accordance with an embodiment;

FIG. 4 is a settings graphical user interface of the handheld electronic device of FIG. 2 illustrating a control setting for the adjustable touch keypad, in accordance with an embodiment;

FIG. 5 is an illustration of an adjustable touch keypad where a typographical error has been entered, in accordance with an embodiment;

FIG. 6 illustrates other typographical errors that may occur over a time period of use of the adaptable touch keypad, in accordance with an embodiment;

FIG. 7 illustrates increasing the size of a key based upon a typographical error history, in accordance with an embodiment;

FIG. 8 illustrates increasing the spacing between keys based upon a typographical error, in accordance with an embodiment;

FIG. 9 illustrates modifying key shapes based upon a typographical error, in accordance with an embodiment;

FIG. 10 illustrates an adaptable touch keypad where the graphical representation of the keys has been modified based upon the typographical error statistics, in accordance with an embodiment; and

FIG. 11 illustrates an adaptable touch keypad where the graphical representation of the keys has not been modified based upon the typographical errors, in accordance with an embodiment.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

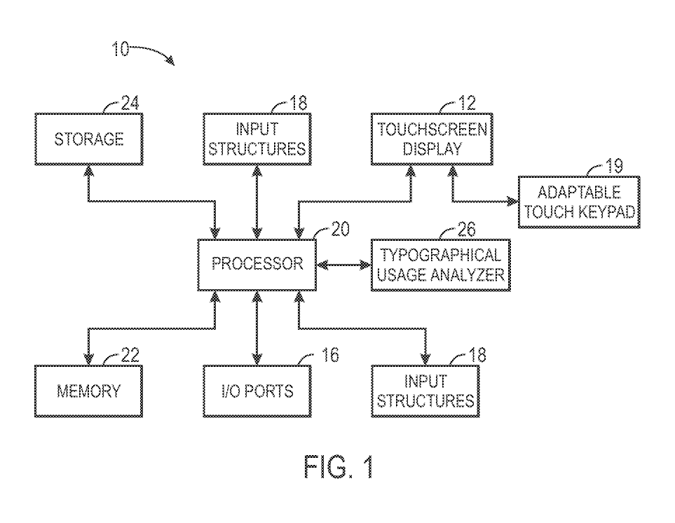

As may be appreciated, electronic devices may include various components that contribute to the function of the device. For instance, FIG. 1 is a block diagram illustrating components that may be present in one such electronic device 10. Those of ordinary skill in the art will appreciate that the various functional blocks shown in FIG. 1 may include hardware elements (including circuitry), software elements (including computer code stored on a computer-readable medium, such as a hard drive or system memory), or a combination of both hardware and software elements. FIG. 1 is only one example of a particular implementation and is merely intended to illustrate the types of components that may be present in the electronic device 10. For example, in the presently illustrated embodiment, these components may include a touch screen display 12, input/output (I/O) ports 16, input structures 18 that include an adaptable touch keypad 19, one or more processors 20, one or more memory devices 22, non-volatile storage 24, and a typographical usage analyzer 26.

The touch screen display 12 may be used to display various images generated by the electronic device 10. For example, the processor 20 may provide image data to the touch screen display 12. Further, the non-volatile storage 24 may be configured to store image data provided by the processor 20. The touch screen display 12 may be any suitable liquid crystal display (LCD), such as a fringe-field switching (FFS) and /or an in-plan switching (IPS) LCD. Additionally, the touch screen display 12 may have touch-sensing capabilities that may be used as part of the control interface for the electronic device 10.

The touch screen display 12 may provide an adaptable touch keypad 19 generated and controlled by the processor 20. As will be described in more detail below with respect to FIG. 5, the adaptable touch keypad 19 includes graphical representation regions 78 for one or more keys 90 of the adaptable touch keypad 19. The graphical representation regions 78 are provided on the touch screen display 12. The adaptable touch keypad 19 also includes input regions 80 for each of the keys 90 of the adaptable touch keypad 19. The input regions 80 define the boundaries of the touch inputs on the touch sensitive element for each of the keys 90.

The typographical usage analyzer 26 may include instructions stored in memory 22 or storage 24 that run on the processors 20. The typographical usage analyzer 26 may detect the usage of the adaptable touch keypad 19. For example, the typographical usage analyzer 26 may monitor a usage of the adaptable touch keypad 19. Further, the typographical usage analyzer 26 may analyze the usage to determine usage statistics such as a frequency of key usage, typographical errors that occur, and a frequency of typographical error occurrence. The adaptable touch keypad 19 may adapt (e.g., change the key layout, which may include the graphical representation and/or the input regions of the keys 90) based upon the usage statistics.

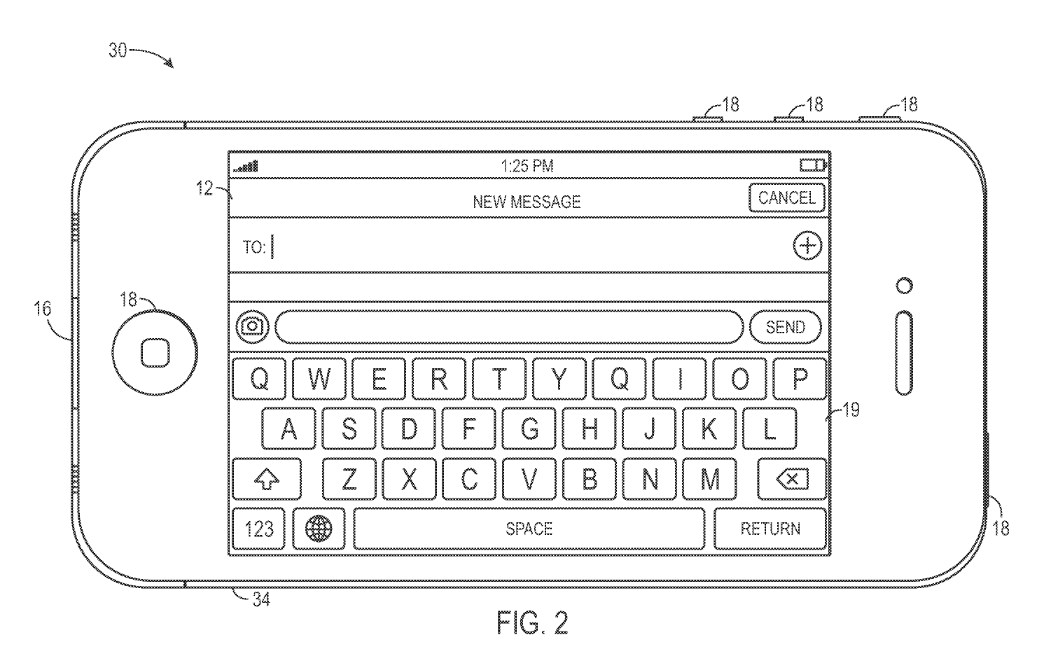

The electronic device 10 may take the form of a cellular telephone or some other type of electronic device. In certain embodiments, the electronic device 10 in the form of a handheld electronic device may include a model of an iPod® or iPhone® available from Apple Inc. of Cupertino, Calif. By way of example, an electronic device 10 in the form of a handheld electronic device 30 (e.g., a cellular telephone) is illustrated in FIG. 2 in accordance with one embodiment. The depicted handheld electronic device 30 includes a housing 34, a touch screen display 12 (e.g., in the form of an LCD or some other suitable display), I/O ports 16, and input structures 18.

In the depicted embodiment, the handheld electronic device 30 includes the touch screen display 12. The touch screen display 12 may display various images generated by the handheld electronic device 30, such as a graphical user interface (GUI) 38 having an adaptable touch keypad 19. A user may interact with the handheld device 30 by touching the display and accessing the graphical user interface 38.

Although the electronic device 10 is generally depicted in the context of a cellular phone in FIG. 2, an electronic device 10 may also take the form of other types of electronic devices. In some embodiments, various electronic devices 10 may include media players, personal data organizers, handheld game platforms, cameras, and combinations of such devices. For instance, the device 10 may be provided in the form of handheld electronic device 30 that includes various functionalities (such as the ability to take pictures, make telephone calls, access the Internet, communicate via email, record audio and video, listen to music, play games, and connect to wireless networks). In another example, the electronic device 10 may also be provided in the form of a portable multi-function tablet computing device. By way of example, the tablet computing device may be a model of an iPad® tablet computer, available from Apple Inc. Alternatively, the electronic device 10 may also be provided in the form of a desktop or notebook computer with the touch screen display 12. For example, the desktop or notebook computer may be a model of an iMac®, MacBook Air®, or MacBook Pro® equipped with a touch screen display 12. Although the following disclosure uses the handheld device 30 by way of example, it should be understood that the adaptable touch keypad 19 may be employed in like fashion in an electronic device 10 of any suitable form factor, such as those mentioned above.

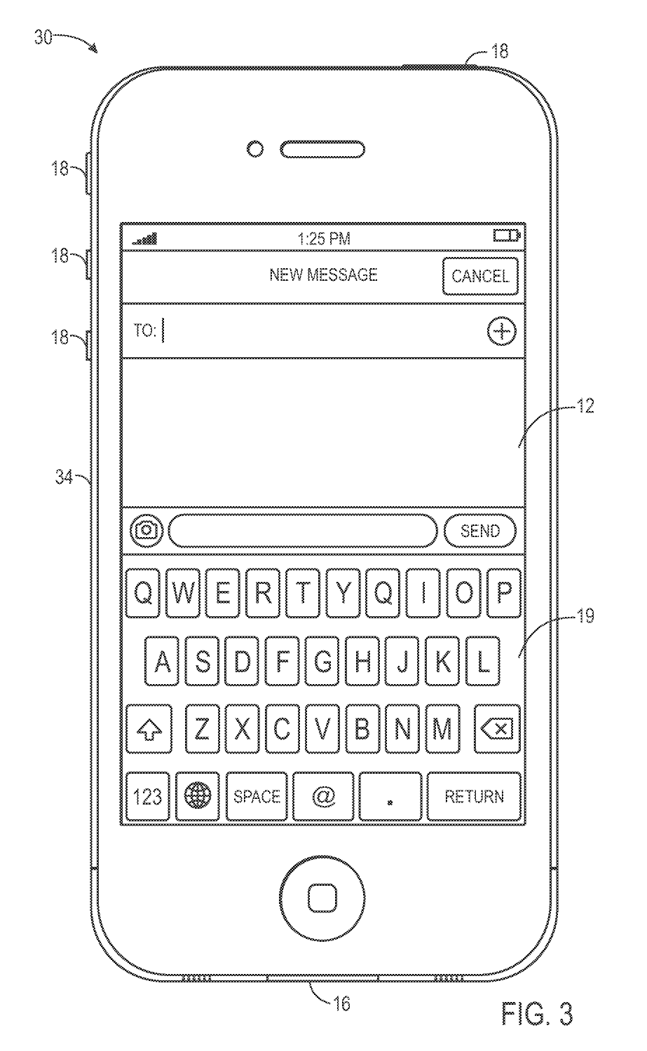

The adaptable touch keypad 19 may adjust based upon the orientation of the handheld electronic device 30. For example, as illustrated in FIG. 2, the handheld electronic device 30 may be oriented in a landscape orientation (e.g. the sides of the touch screen display 12 are oriented to display the top and bottom of images depicted on the touch screen display 12). In the landscape orientation, the adaptable touch keypad 19 may span the entire length of the side of the touch screen display 12. When the handheld electronic device 30 is oriented in the portrait orientation (e.g., the top and bottom of the touch screen display 12 are oriented to display the top and bottom of images depicted on the touch screen display 12), as depicted in FIG. 3, the adaptable touch keypad 19 may span the length of the bottom of the touch screen display 12.

The typographical usage analyzer 26 of FIG.1 may be used to monitor the usage of the adaptable touch keypad 19 in both the landscape orientation of FIG. 2 and the portrait orientation of FIG. 3. The key layout (e.g., the size, spacing, and shape of the keys 90 of the adaptable touch keypad 19) may differ based upon the orientation of the handheld electronic device 30. Thus, the typographical usage analyzer 26 may provide separate usage statistics (e.g., a usage profile) for adaptable touch keypads 19 that have variances in the key layout. Maintaining separate usage profiles may ensure that external variances do not erroneously influence the monitoring and analysis of the key usage. For example, usage profiles may exist for language specific keypads, country specific keypads, orientation specific keypads, or a combination thereof. Further, usage profiles may exist for different adaptable keypad users. For example, the handheld electronic device 30 may detect a specific user (e.g., through logging into the handheld electronic device 30) and the typographical usage analyzer 26 may monitor and analyze the user's specific usage profile.

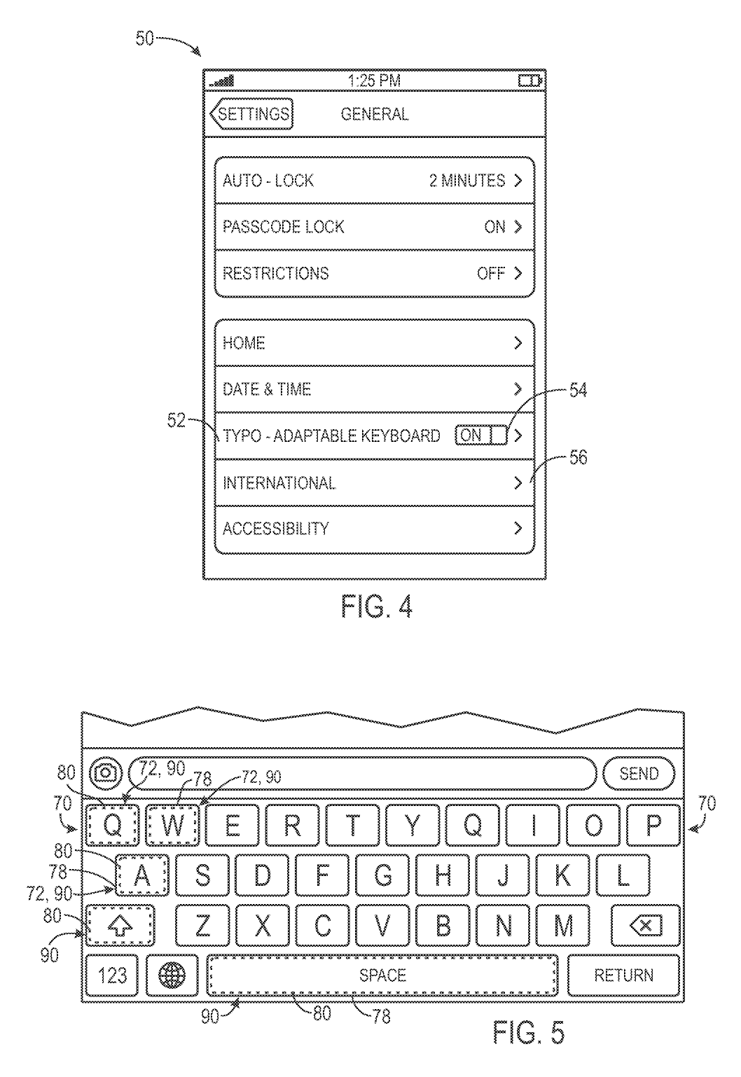

Under certain conditions, a user of the handheld electronic device 30 may desire to disable the adaptability functionality of the adaptable touch keypad 19. By way of example, the adaptable touch keypad may be activated and deactivated through a menu 50 of the handheld electronic device 30. An embodiment of such a menu screen is depicted in FIG. 4. As illustrated, the menu 50 may include an adaptable touch keypad setting 52 that enables a user to activate or deactivate the adaptability functions of the keypad. For example, the adaptable touch keypad setting 52 may include a toggle switch 54 that turns the functionality on or off. In other embodiments, the menu 50 may include additional settings for the adaptable touch keypad 19. For example, the menu 50 may include a reset feature that clears the active usage profile.

The menu 50 may also include an international selector 56 that allows a user to change the adaptable touch keypad 19 to an international keypad (e.g., a keypad for a specific country and/or language). As previously mentioned, when a different keypad is selected, a new usage profile is created for the different keypad or, if a usage profile already exists for the different keypad, the existing usage profile is accessed. Thus, the proper usage profile may be automatically selected based upon the keypad settings. Further, in certain embodiments, a particular usage profile may be adapated. For example, an English keypad may include an identical key layout as a Spanish keypad but access different spell-check databases. Upon selecting the Spanish keypad (with the identical key layout), the usage profile may be adapted to use the new spell-check database.

Upon first use of the adaptable touch keypad 19, a default key layout 70 may be presented. Upon subsequent typographical usage analysis, the key layout may be altered. FIG. 5 illustrates an adaptable touch keypad 19 where a default key layout 70 is presented. As illustrated, the default key layout 70 may provide a QWERTY keyboard where alpha-keys 72 are substantially evenly spaced and sized. With the default key layout 70, more typographical errors may be present than a key layout personalized based upon a user's analyzed key usage. For example, in the illustration of FIG. 5, a typing box 74 may provide a graphical representation of words being typed by a user. In the current example, a user may desire to type the word “SEND” and instead accidentally press the W in combination with the S, forming the word “S WEND”.

In certain embodiments, the typographical usage analyzer 26 may represent a background application or process that monitors a user's key usage on the adaptable touch keypad 19. In some embodiments, the typographical usage analyzer 26 may represent an operating system process or service. The typographical usage analyzer 26 may determine any suitable usage statistics including, for example, a frequency of key use, a typographical error, and/or a typographical error frequency. In the example illustrated in FIG. 5, the typographical usage analyzer 26 may detect that the W was incorrectly selected. The typographical usage analyzer 26 may detect such a typographical error in many ways. For example, in some embodiments, the adaptable touch keypad may automatically suggest a word when a misspelled word is detected. When the suggested word is selected over the typed word, the typographical usage analyzer 26 may detect the typographical error by comparing the selected suggested word to the typed word. For example, if the user types “SWEND” and is suggested the word “SEND”, which the user selects, the typographical usage analyzer 26 may detect that the W was a typographical error.

In certain embodiments, typographical errors may be detected when a user manually corrects a misspelled word. For example, the typographical usage analyzer may monitor touch commands by the user such as pressing the backspace key or repositioning the cursor in the typing box 74 and modifying a typed word. In the current example, the typographical usage analyzer 26 may detect that a user has repositioned the cursor after the W and pressed the backspace key to remove the W. Alternatively, the user may have pressed the backspace key 4 times at the end of “SWEND” to remove “WEND” and then typed “END”. In either scenario, the typographical usage analyzer 26 may detect that the user removed the W while retaining the rest of the word. Thus, the typographical usage analyzer 26 may detect that the W was a typographical error.

The detection methods discussed above are merely provided for example. Any other suitable typographical error detection methods may be used. The current discussion is not meant to limit the detection techniques in any way.

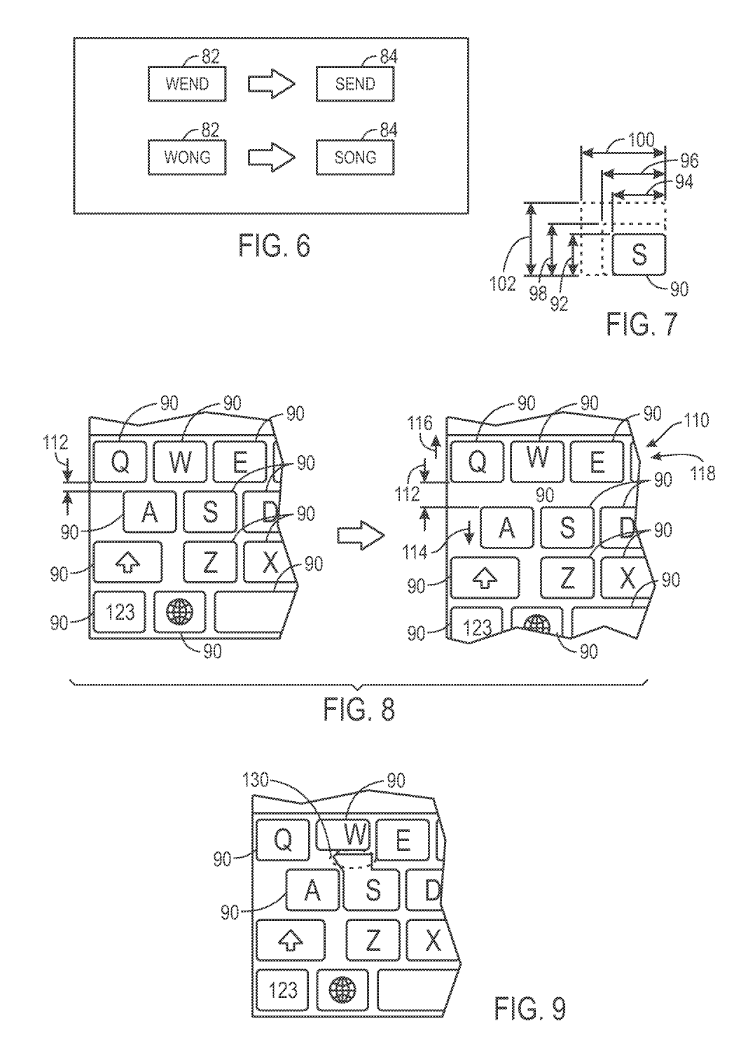

Over time, a pattern of typographical errors may be detected. For example, as illustrated in FIG. 6, a user may repeatedly mis-select the W key when attempting to select S. For example, as illustrated, the user may make an initial selection 82 of the words “WEND” and “WONG” intending to instead form resultant words 84 “SEND” and “SONG”, respectively. Over time, the typographical usage analyzer 26 may detect a pattern in the typographical errors. For example, through historical analysis of the typographical errors, the typographical usage analyzer 26 may determine that W is often chosen when S is intended. The typographical usage analyzer 26 may also detect other usage patterns such as key usage frequencies (e.g., the number of times a key is selected), a frequency of combinations of letters (e.g., the letter H may be frequently selected after the letter T), or any other key usage pattern.

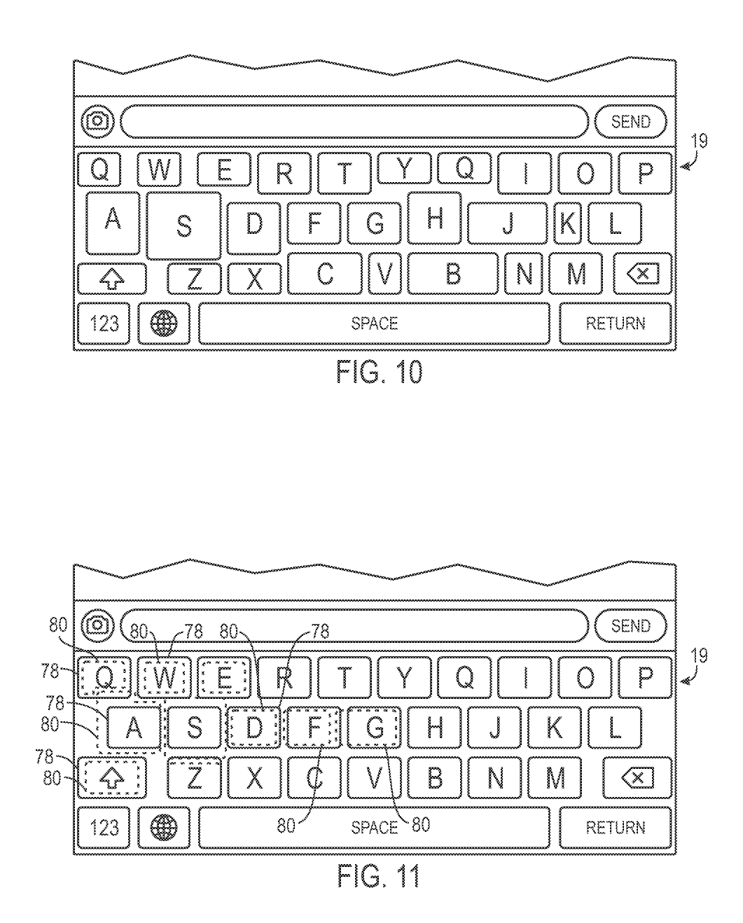

The typographical usage analyzer 26 may provide key usage statistics and patterns to the adaptable touch keypad 19, which may in turn adapt the key layout (e.g., key spacing , shape, and or size of the graphical representation regions 78 and/or input regions 80 of the keys 90 on the keypad). For example, FIGS. 7-11 illustrate embodiments where the adaptable touch keypad 19 is adapted with a modified keypad layout. FIGS. 7-9 illustrate various modifications to the keys 90 in the key layout and FIGS. 10 and 11 illustrate resultant keypad layouts for the adaptable touch keypad 19. As will be described in more detail with regards to FIGS. 10 and 11, the modifications illustrated in FIGS. 7-9 may be applied to the graphical representation regions 78 and the input regions 80 of each key 90 in the adaptable touch keypad 19, or the modifications may be applied merely to the input regions 80 of each key 90, leaving the graphical representation regions 78 of the adaptable touch keypad 19 unaffected. For example, FIG. 7 illustrates an embodiment where the adaptable touch keypad 19 may adjust the size of keys 90. Continuing with the typographical error pattern example discussed above, the S key may be increased or decreased in size when typographical usage patterns are detected with the S key. The adaptable touch keypad 19 may gradually adjust the height and/or width of the keys 90. For example, the height and/or width of the keys may be slowly adjusted such that the change may not be detectable by a user of the adaptable touch keypad 19. As illustrated in FIG. 7, the height 92 and the width 94 may be increased to an intermediate height 96 and/or an intermediate width 98. If the typographical errors continue, the adaptable touch keypad 19 may continue to change the height 96 and/or width 98 to a maximum height 100 and/or a maximum width 102. As discussed previously, the key layout changes for the size of the keys 90 may relate to the graphical representation regions 78 of the keys and the input regions 80 of the keys 90, or may merely relate to the input regions 80 of the keys 90, leaving the graphical representation regions 78 unaffected. Further, the size adjustments of keys 90 may be limited by upper and lower sizing thresholds such that the keys 90 do not exceed a certain size or fall below a certain size.

The key layout may also be modified by modifying the key spacing of the keys 90. For example, if the typographical usage analyzer 26 detects that the W key is selected when the S key is pressed, the key layout may be altered to further separate the S and W keys. FIG. 8 illustrates an embodiment of the adaptable touch keypad 19 that modifies the key layout through modifying the spacing of the keys 90. As illustrated, the default key layout 70 may be adapted to a modified spacing layout 110. In certain embodiments, the adaptable touch keypad 19 may modify only keys 90 involved in the detected typographical usage pattern. For example, in the S and W key example discussed above, the adaptable touch keypad 19 may modify the key layout by increasing the spacing 112 between the S and W keys. The spacing 112 may be increased by shifting the S key down 114 or by shifting the W key up 116. In other embodiments, the key layout may be modified by altering an entire row 118 of keys. For example, row 118 may be shifted up to increase the spacing between the S and W keys. As discussed previously, the key layout changes for the spacing of the keys 90 may relate to the graphical representation regions 78 of the keys 90 and the input regions 80 of the keys 90, or may merely relate to the input regions 80 of the keys 90, leaving the graphical representation regions 78 unaffected.

In some embodiments, the key layout may be modified by adjusting a shape of the keys 90. For example, FIG. 9 depicts such a key shape modification. Continuing with the example discussed above, upon detecting a pattern of W being selected when the S key is pressed, the adaptable touch keypad 19 may alter the shape of the S key, the W key, or a combination of both the S and W keys. In some embodiments, the typographical usage analyzer 26 may detect that a specific portion of a mis-selected key is selected when the intended key is selected. In accordance with the current example, the typographical usage analyzer 26 may detect that a specific portion of the W key is often mistakenly selected when the S key is selected. The key layout may be modified such that the S key may be re-shaped to cover the portion 130 of area where the W key is typically pressed in conjunction with the S key. As previously discussed, while the current embodiment illustrates the graphical representation regions 78 of the keys as modified, in certain embodiments the input regions 80 of the keys 90 may be modified without altering the graphical input regions 78 of the keys 90. Thus, the graphical representation of the keypad may remain consistent while altering the input regions based upon the detected typographical usage patterns.

As previously discussed, the graphical representation regions 78 of the keys 90 may not be altered as the adaptable touch keypad 19 adapts to typographical usage patterns. FIGS. 10 and 11 illustrate embodiments of the adaptable touch keypad 19 comparing an embodiment where the graphical representation regions 78 of the keys 90 are modified with an embodiment where the graphical representation regions 78 are not modified. In some embodiments, it may be desirable to provide dynamically modified graphical representation regions 78. Such embodiments might provide an enhanced user experience by allowing a user to see how their adaptable touch keypad 19 is being dynamically modified based upon the user's typographical usage patterns. FIG. 10 illustrates the adaptable touch keypad 19 where the graphical representation regions 78 of the keys 90 have been adapted based upon the detected typographical usage patterns. Thus, as illustrated, the adaptable touch keypad 19 may provide a graphical representation of the key layout changes that have been adapted to the typographical usage patterns, enabling a user of the adaptable touch keypad 19 to understand the key layout modifications.

In some embodiments, it may be desirable to maintain a uniform graphical representation of the adaptable touch keypad 19, as the key layout is modified. For example, modifying the graphical representation regions 78 of the keys 90 may affect the typographical usage patterns by causing a user to see graphical representation variations and make typographical usage variations based upon the graphical representation variations. Thus, maintaining a uniform graphical representation may help to ensure stable typographical usage patterns. FIG. 11 illustrates an embodiment of the adaptable touch keypad 19 where the graphical representation regions 78 of the keys 90 have not been affected by the key layout modifications. As illustrated, while the graphical representation regions 78 of the keys 90 have not been altered from the default key layout 70, the input regions 80 have adapted to the detected typographical usage patterns. The input regions 80 may be modified in any manner described above (e.g., the size, shape, and/or spacing of the input regions 80 may be modified). For example, in the illustrated embodiment, the input region 80 of the S key has increased in size and the input regions 80 of the Z and X keys have been reshaped. Further, the input regions 80 of the A key and the Q key have been resized and the input regions 80 of the F and G key have been shifted left.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

What is claimed is:

1. A method comprising:
providing, on a touch screen of an electronic device, a keypad with a plurality of keys aligned in a key layout, the key layout comprising:
a plurality of input regions, wherein each input region is configured to define touch input boundaries representing a respective one of the plurality of keys; and
a plurality of graphical representation regions, wherein each graphical representation region is configured to provide a graphical representation of a respective one of the plurality of keys;
monitoring, via a processor of the electronic device, a usage pattern of the keypad; and
modifying, via the processor of the electronic device, the key layout based at least in part upon the usage pattern.

2. The method of claim 1, wherein monitoring the typographical usage comprises monitoring a frequency of key usage.

3. The method of claim 2, wherein monitoring the frequency of key usage comprises monitoring a frequency of usage of a combination of keys.

4. The method of claim 2, wherein modifying the key layout comprises increasing a size of one of the plurality of input regions corresponding to one of the plurality of keys with a relatively higher frequency of key usage, increasing a size of one of the plurality of representation regions corresponding to the one of the plurality of keys with the relatively higher frequency of key usage, or increasing the size of one of the plurality of input regions and one of the representation regions corresponding to the one of the plurality of keys with the relatively higher frequency of key usage or decreasing a size of one of the plurality of input regions corresponding to one of the plurality of keys with a relatively lower frequency of key usage, decreasing a size of one of the plurality of representation regions corresponding to the one of the plurality of keys with the relatively lower frequency of key usage, or decreasing the size of one or more of the plurality of representation regions, or both, of keys with a relatively lower key frequency of usage, or decreasing the size of one of the plurality of input regions and one of the representation regions corresponding to the one of the plurality of keys with the relatively lower frequency of key usage.

5. The method of claim 2, wherein modifying the key layout comprises modifying a spacing of one or more of the plurality of input regions, one or more of the plurality of representation regions, or both, of one or more keys based at least in part upon the frequency of key usage.

6. The method of claim 1, wherein monitoring the usage pattern of the keypad comprises detecting a typographical error in the usage pattern of the keypad.

7. The method of claim 6, wherein detecting the typographical error comprises detecting a manual correction and associating the manual correction with the typographical error.

8. The method of claim 6, wherein detecting the typographical error comprises detecting an auto correction by the electronic device and associating the auto correction with the typographical error.

9. The method of claim 6, wherein modifying the key layout comprises modifying a size of one or more of the plurality of input regions or one or more of the plurality of representation regions, or both, of the keys based at least in part upon the typographical error.

10. The method of claim 6, wherein modifying the key layout comprises modifying a spacing of one or more of the plurality of input regions, one or more of the plurality of representation regions, or both, of one or more of the keys based at least in part upon the typographical error.

11. The method of claim 1, wherein modifying the key layout comprises modifying a size, a spacing, a shape, or a combination thereof, of one or more of the plurality of input regions, one or more of the plurality of graphical representation regions, or both, of one or more of the plurality of keys.

12. The method of claim 1, wherein modifying the key layout comprises modifying one or more of the plurality of input regions of one or more of the plurality of keys, but not any of the plurality of graphical representation regions of any of the plurality of keys.

13. The method of claim 1, wherein modifying the key layout comprises modifying one or more of the plurality of input regions of one or more of the plurality of keys and modifying one or more of the plurality of graphical representation regions associated with the modified input regions.

14. A system comprising:
a touch screen display, configured to receive a touch input and provide a graphical image;
a memory, configured to store touch input statistics of the touch screen display; and
a processor configured to execute instructions to:
present a graphical user interface on the touch screen display, the graphical user interface comprising a keypad with a plurality of keys aligned in a key layout, the key layout comprising:
a plurality of input regions, each input region corresponding to one of the plurality of keys, the input regions configured to define touch input boundaries for each of the plurality of keys; and
a plurality of graphical representation regions, each graphical representation region corresponding to one of the plurality of keys, the graphical representation regions configured to provide a graphical representation of each of the plurality of keys;
store typographical usage statistics of the keypad in the memory;
access the typographical usage statistics of the keypad from the memory;
analyze the typographical usage statistics of the keypad; and
modify at least a portion of the key layout based at least in part on the typographical usage statistics.

15. The system of claim 14, wherein the processor is configured to execute instructions to analyze the typographical usage statistics by detecting typographical errors in the typographical usage.

16. The system of claim 15, wherein the processor is configured to execute instructions to modify the at least portion of the key layout by modifying a size or spacing, or both, of the input region, the representation region, or both, of one or more of the plurality of keys gradually until the typographical errors are no longer detected.

17. The system of claim 14, wherein the processor is configured to execute instructions to modify the at least portion of the key layout by modifying the height of the input regions, the representation regions, or both, for an entire row of keys.

18. The system of claim 14, wherein the keypad is configured to be switched to an international keypad upon a user selection of an international keypad selector and an additional set of typographical usage statistics is stored when the keypad is selectively switched to the international keypad.

19. The system of claim 14, wherein when the touch screen display is turned 90 degrees, the keypad is aligned in a second key layout and a second set of typographical usage statistics is stored, accessed, and analyzed for the keypad .

20. The system of claim 14, wherein the processor is configured to execute instructions to selectively purge the stored typographical statistics upon a user request.

21. A non-transitory tangible computer-readable medium comprising executable code, the code comprising:
instructions to analyze a typographical usage of a touch screen keypad having a plurality of keys, and
instructions to modify a key layout of the touch screen keypad based at least in part upon the analyzed typographical usage;
wherein modifying the key layout comprises modifying at an input region, a representation, or both, for one or more of the plurality of keys, the input region defining touch input boundaries for each of the plurality of keys and the representation region providing a graphical representation of each of the plurality of keys.

22. The non-transitory tangible computer-readable medium of claim 21, wherein the code comprises:
instructions to present a user-selectable option to disable modification of the layout; and
instructions to disable the modification of the key layout based at least in part upon a user selection of the option.

23. The non-transitory tangible computer-readable medium of claim 21, wherein the analyzed typographical usage comprises a selection of an unintended key in combination with the selection of an intended key.

24. The non-transitory tangible computer-readable medium of claim 23, wherein modifying the key layout comprises modifying a shape of the input region, the graphical representation region, or both, of the intended key to cover an area where the unintended key was selected.
